(19) United States
(12) Patent Application Publication
(10) Pub. No.: US 2006/0281210 A1
(43) Pub. Date: Dec. 14, 2006

(54) Semiconductor device manufacturing method

(75) Inventors: Kenji Kiuchi, Kawasaki (JP); Genichi Komuro, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/224,996

(22) Filed: Sep. 14, 2005

(30) Foreign Application Priority Data
Jun. 8, 2005 (JP) 2005-168610

(51) Int. Cl. H01L 21/00

(52) U.S. Cl. 438/30

(57) ABSTRACT

A semiconductor device manufacturing method includes a step of forming an oxidation preventing film 25 on a contact plug 22a on a silicon substrate 10, a step of forming a capacitor Q on the oxidation preventing film 25, a step of forming a second interlayer insulating film 44 to cover the capacitor Q, a step of forming a first hole 44a in the second interlayer insulating film 44, a step of applying a brush scrubbing process to the second interlayer insulating film 44, a step of applying a wet process to the second interlayer insulating film 44, a step of forming a second hole 44c in the second interlayer insulating film 44 by using the oxidation preventing film 25 as a stopper, a step of etching the oxidation preventing film 25 under the second hole 44c to remove and also cleaning an upper electrode 33a under the first hole 44a, and a step of forming first and second conductive plugs 50a, 50c in the first and second holes 44a, 44c.

### CROSS-REFERENCE TO RELATED APPLICATIONS

This application is based on and claims priority of Japanese Patent Application No. 2005-168610 filed on Jun. 8, 2005, the entire contents of which are incorporated herein by reference.

### BACKGROUND OF THE INVENTION

1. Field of the Invention

The present invention relates to a semiconductor device manufacturing method.

2. Description of the Related Art

As the nonvolatile memory that can store information after a power supply is turned off, the flash memory and the ferroelectric memory are known.

Out of them, the flash memory has a floating gate that is buried in a gate insulating film of an insulated-gate field effect transistor (IGFET), and stores information by accumulating a charge representing information in this floating gate. However, flash memory possesses a defect that, since a tunnel current must be supplied to the gate insulating film in writing or erasing the information, a relatively high voltage is required.

In contrast, the ferroelectric memory, called also FeRAM (Ferroelectric Random Access Memory), stores information by utilizing the hysteresis characteristic of a ferroelectric film that a ferroelectric capacitor has. In this ferroelectric film, the polarization occurs in response to a voltage applied between an upper electrode and a lower electrode of the capacitor, and the spontaneous polarization remains after the voltage is removed. This spontaneous polarization is reversed when the polarity of the applied voltage is reversed. Thus, the information can be written into the ferroelectric film by relating respective directions of the spontaneous polarization to “1” and “0”. The FeRAM has such advantages that a voltage required for the writing is lower than that in the flash memory and the information can be written at a higher speed than the flash memory.

The capacitor of the FeRAM is covered with an interlayer insulating film, and holes used to make an electrical contact with these electrodes are opened in the interlayer insulating film on the upper electrode and the lower electrode. Also, for the purpose of making contact with source/drain regions of the MOS transistor on the semiconductor substrate, holes are formed in the interlayer insulating film in the position that is away from the capacitor. If the extraneous substance is present in these holes or the holes themselves are not opened, the contact failure is brought on between the conductive plugs formed in the holes and the underlying electrodes. If this is the case, a desired voltage cannot be applied to the capacitor, and thus the FeRAM becomes defective and a yield is decreased.

Here, the technologies relating to the present invention are set forth in following Patent Literatures 1 to 3.

In Patent Literature 1, polymer generated by the plasma etching is removed by the brush scrubbing process.

Also, in Patent Literatures 2, 3, the brush scrubbing process is applied after the CMP (Chemical Mechanical Polishing).
[Patent Literature 1] Patent Application Publication (KOKAI) 2001-237236
[Patent Literature 2] Patent Application Publication (KOKAI) 2002-373879
[Patent Literature 3] Japanese Patent No. 3332831

### SUMMARY OF THE INVENTION

According to an aspect of the present invention, there is provided a semiconductor device manufacturing method, which includes a step of forming a MOS transistor on a semiconductor substrate; a step of forming a first interlayer insulating film on the MOS transistor; a step of forming a contact hole in the first interlayer insulating film on a source/drain region of the MOS transistor; a step of forming a contact plug connected electrically to the source/drain region in the contact hole; a step of forming an oxidation preventing film on the first interlayer insulating film and the contact plug respectively; a step of forming a capacitor having a lower electrode, a capacitor dielectric film, and an upper electrode on the oxidation preventing film; a step of forming a second interlayer insulating film that covers the capacitor; a step of forming a first hole having a depth, which reaches the upper electrode, in the second interlayer insulating film by patterning the second interlayer insulating film; a step of applying a brush scrubbing process to a surface of the second interlayer insulating film after the second interlayer insulating film is patterned; a step of applying a wet process to the surface of the second interlayer insulating film after the brush scrubbing process; a step of forming a second hole in the second interlayer insulating film on the contact plug by patterning the second interlayer insulating film, while using the oxidation preventing film as an etching stopper, after the wet process; a step of etching the oxidation preventing film exposed from the second hole to expose an upper surface of the contact plug and also cleaning an upper surface of the upper electrode exposed from the first hole, by exposing inner surfaces of the first and second holes to an etching atmosphere; a step of forming a first conductive plug connected electrically to the upper electrode in the first hole; and a step of forming a second conductive plug connected electrically to the contact plug in the second hole.

According to the present invention, since the etching product generated in forming the first hole is physically scraped off by the brush scrubbing process, the etching product can be surly removed rather than the case where the etching product is chemically dissolved like the wet process. Therefore, it can be prevented that the pattern failure is generated due to the presence of the etching product when the second hole is formed by patterning the second interlayer insulating film. As a result, it can be suppressed that the second hole is not opened and then the contact failure is generated between the second conductive plug formed in the second hole and the underlying contact plug, and also it can be prevented that the finally completed semiconductor device becomes defective.

In addition, the oxidation preventing film is formed on the contact plug. Therefore, it can be prevented that the contact plug is oxidized in manufacturing the semiconductor device, and also the contact failure owing to the oxidation can be suppressed.

The oxidation preventing film is removed by exposing the inner surfaces of the first and second holes to the etching atmosphere. At this time, since the surface of the upper electrode exposed from the first hole is cleaned, the first conductive plug formed in the first hole and the upper electrode can be connected electrically satisfactorily.

As the second interlayer insulating film, it is preferable to form laminated film containing the alumina film, which blocks the reducing substance, such as the hydrogen, and is excellent in preventing the capacitor dielectric film from being reduced.

In this case, it follows that the alumina is contained in the etching product generated when forming the first hole. This alumina can easily be removed by exposing the surface of the second interlayer insulating film to hot water in the step of the wet process after the brush scrubbing process.

### BRIEF DESCRIPTION OF THE DRAWINGS

FIGS. 1A to 1N are sectional views of the FeRAM in Preliminary Explanation in the middle of manufacture;

FIG. 2 is a view of a first hole and a second hole drawn based on their SEM images after the steps in FIG. 1I in Preliminary Explanation are completed;

FIG. 3 is a view of the first hole drawn based on its SEM image after the steps in FIG. 1J in Preliminary Explanation are completed;

FIGS. 4A to 4H sectional views of a semiconductor device according to an embodiment of the present invention in the middle of manufacture;

FIG. 5 is a view of a first hole and a second hole drawn based on their SEM images after the brush scrubbing process in FIG. 4A is completed;

FIG. 6 is a view of the first hole and the second hole drawn based on their SEM images after the first step of the wet process in FIG. 4B is completed; and

FIG. 7 is a view of the first hole and the second hole drawn based on their SEM images after the brush scrubbing process in FIG. 4C is completed.

### DESCRIPTION OF THE PREFERRED EMBODIMENTS

(1) Preliminary Explanation

Prior to an embodiment of the present invention, preliminary explanation of the present invention will be made hereunder.

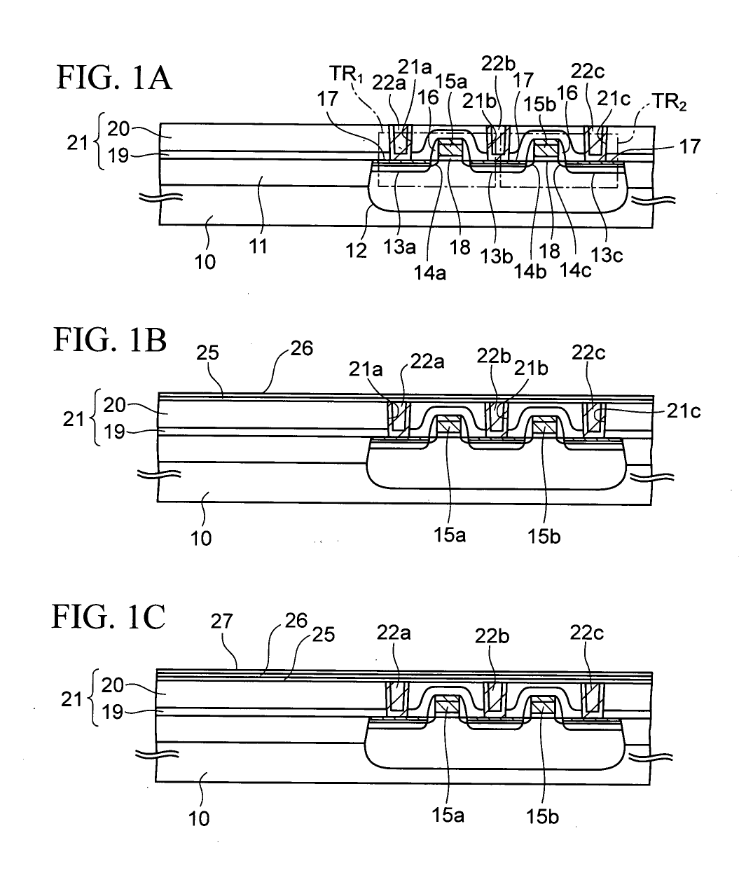

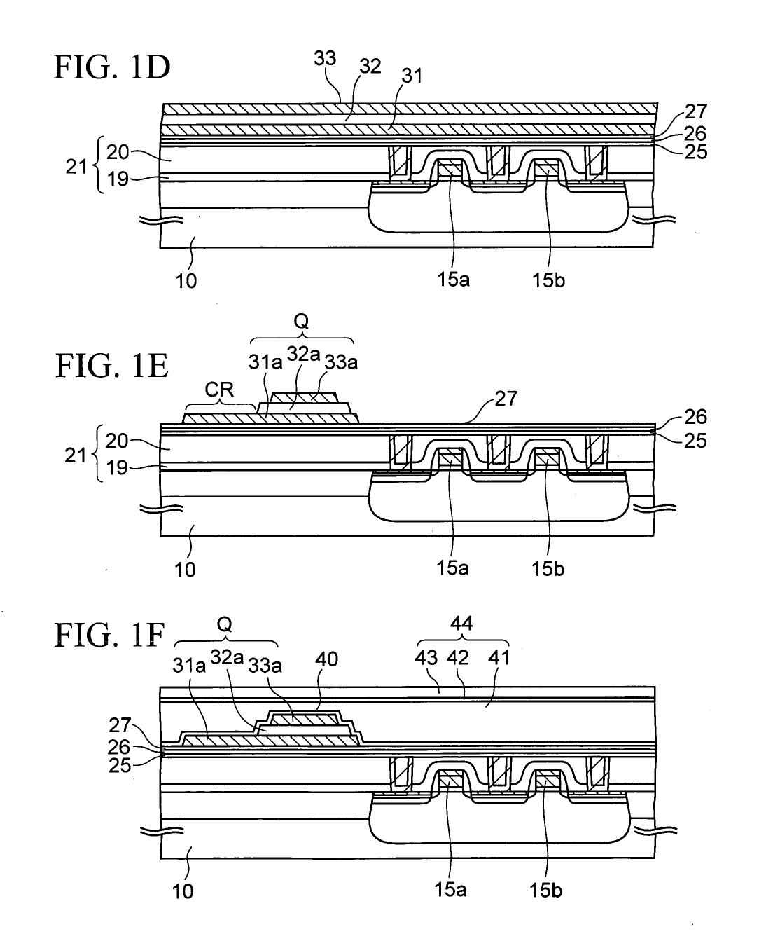

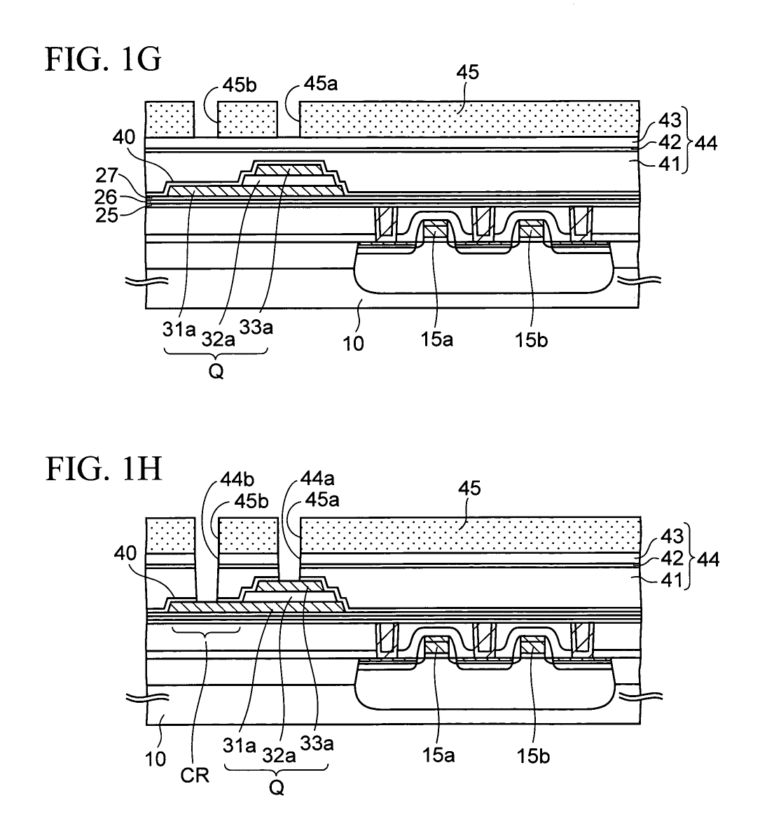

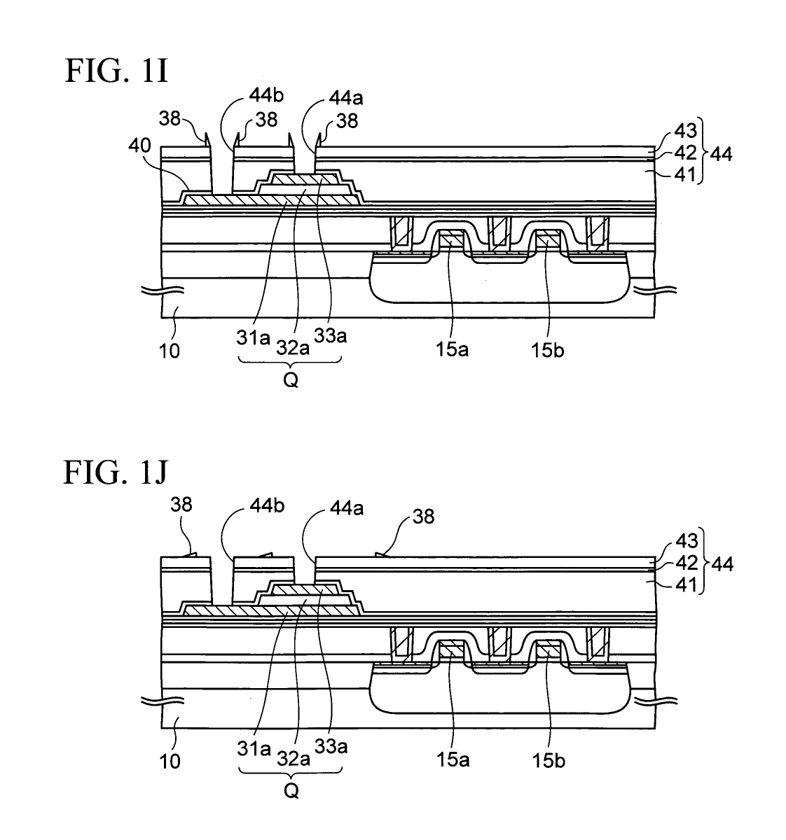

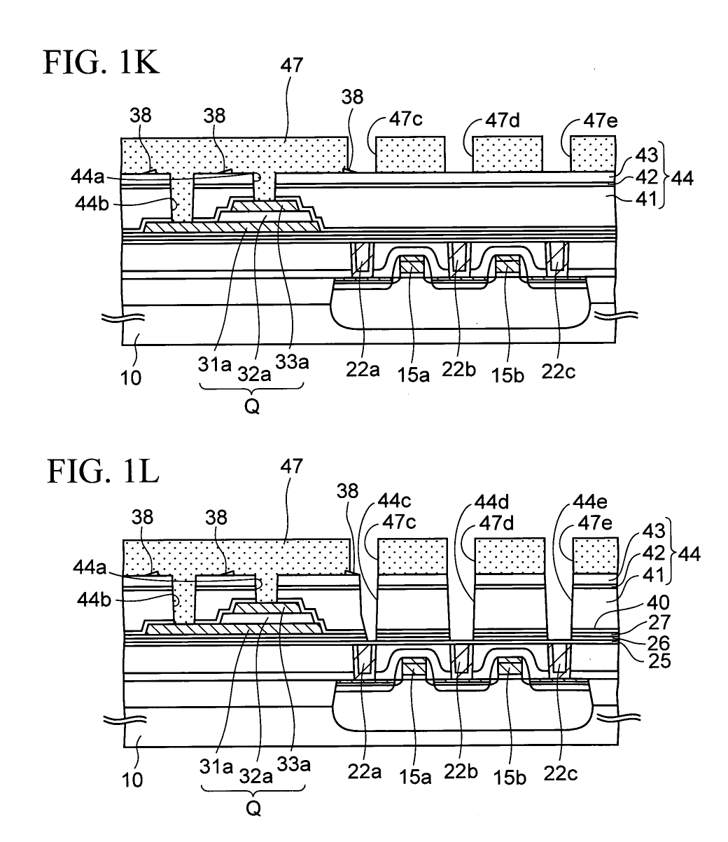

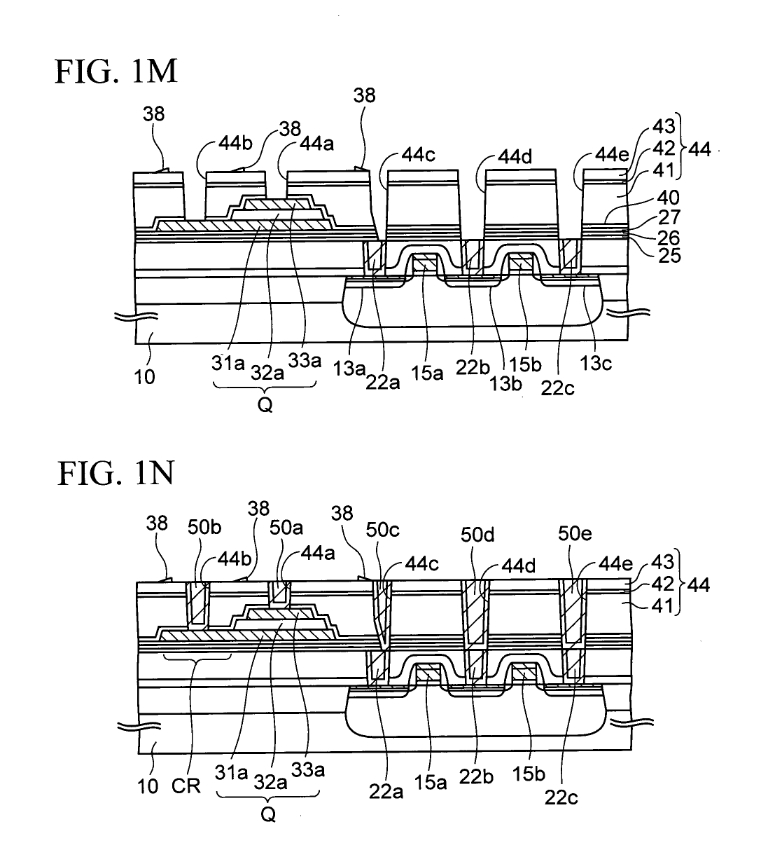

FIGS. 1A to 1N are sectional views of the FeRAM manufactured by the inventors of this application in the middle of manufacture.

This FeRAM is manufactured as follows.

First, the steps required until a sectional structure shown in FIG. 1A is obtained will be explained hereunder.

An STI (Shallow trench Isolation) trench to define an active region of the transistor is formed on a surface of an n-type or p-type silicon (semiconductor) substrate 10. Then, an element isolation insulating film 11 is formed by filling an insulating film such as a silicon oxide film, or the like in the trench. Here, an element isolation structure is not limited to STI, and the element isolation insulating film 11 may be formed by the LOCOS (Local Oxidation of Silicon) method.

Next, a p-well 12 is formed by introducing the p-type impurity into the active region of the silicon substrate 10. Then, a thermal oxide film as a gate insulating film 18 is formed by thermally oxidizing a surface of the active region.

Subsequently, an amorphous silicon film or a polysilicon film and a tungsten silicide film are formed in sequence on an overall upper surface of the silicon substrate 10. Then, gate electrodes 15a, 15b are formed by patterning these films by means of the photolithography.

Two gate electrodes 15a, 15b are formed on the p-well 12 in parallel at an interval. These gate electrodes 15a, 15b constitute a part of the word line.

Next, the n-type impurity is introduced into the silicon substrate 10 on both sides of the gate electrodes 15a, 15b by the ion-implantation, while using the gate electrodes 15a, 15b as a mask. Thus, first to third source/drain extensions 14a to 14c are formed.

Thereafter, an insulating film is formed on the overall upper surface of the silicon substrate 10. An insulating sidewall 16 is left on side surfaces of the gate electrodes 15a, 15b respectively by etching back the insulating film. As such insulating film, a silicon oxide film is formed by the CVD method, for example.

Then, while using the insulating sidewalls 16 and the gate electrodes 15a, 15b as a mask, the n-type impurity is ion-implanted into the silicon substrate 10 again. Thus, first to third source/drain regions 13a to 13c are formed on the silicon substrate 10 on both sides of the gate electrodes 15a, 15b.

With the steps up to now, first and second MOS transistors TR₁, TR₂ consisting of the gate insulating film 18, the gate electrodes 15a, 15b, and the first to third source/drain regions 13a to 13c are formed in the active region of the silicon substrate 10.

Next, a refractory metal layer such as a cobalt layer, or the like is formed on the overall upper surface of the silicon substrate 10 by the sputter method. Then, a refractory metal silicide layer 17 is formed on the silicon substrate 10 by heating the refractory metal layer to react with the silicon. The refractory metal silicide layer 17 is also formed on surface layers of the gate electrodes 15a, 15b, and thereby a resistance of the gate electrodes 15a, 15b is lowered.

Thereafter, the unreacted refractory metal layer left on the element isolation insulating film 11, and the like is removed by the wet etching.

Subsequently, a silicon nitride (SiN) film 19 of about 20 nm thickness is formed by the plasma CVD method. Then, a silicon oxide film 20 of about 80 nm thickness is formed on the silicon nitride film 19 by the plasma CVD method using a silane gas. Next, a sacrifice silicon oxide film of about 1000 nm thickness is formed thereon by the plasma CVD method using a TEOS gas. Then, an upper surface of the sacrifice silicon oxide film is polished and planarized by the CMP (Chemical Mechanical Polishing) method. Thus, the silicon oxide film 20 and the silicon nitride film 19 left thereon constitute a first interlayer insulating film 21. As the result of the CMP, a thickness of the first interlayer insulating film 21 becomes about 700 nm on the planarized surface of the silicon substrate 10.

Next, first to third contact holes 21a to 21c are formed on the first to third source/drain regions 13a to 13c respectively by patterning the first interlayer insulating film 21 by means of the photolithography. Then, a titanium film of about 30 nm thickness and a titanium nitride film of about 20 nm thickness are formed as a glue film in this order on inner surfaces of the first to third contact holes 21a to 21c and an upper surface of the first interlayer insulating film 21 by the sputter method. Furthermore, a tungsten film is formed on the glue film by the CVD method using a tungsten hexafluoride gas such that the contact holes 21a to 21c are completely filled by the tungsten film. Thereafter, the extra tungsten film and the extra glue film on the first interlayer insulating film 21 is polished and removed by the CMP method. Thus, first to third contact plugs 22a to 22c made of these films are left in the contact holes 21a to 21c. These first to third contact plugs 22a to 22c are electrically connected to the underlying first to third source/drain regions 13a to 13c respectively.

By the way, the first to third contact plugs 22a to 22c are made mainly of tungsten. However, the tungsten is very easily oxidized and then the contact failure is brought on when such tungsten is oxidized during the process.

Therefore, as shown in FIG. 1B, in the next step, as an oxidation preventing film 25 for protecting the first to third contact plugs 22a to 22c from the oxidizing atmosphere, a silicon oxide nitride (SiON) film is formed by the plasma CVD method to have a thickness of about 100 nm. In addition, a silicon oxide film of about 130 nm thickness is formed on the oxidation preventing film 25 by the plasma CVD method using the TEOS gas. This silicon oxide film is used as an insulating adhesive film 26.

Then, as shown in FIG. 1C, in order to enhance the crystallinity of the lower electrode of the ferroelectric capacitor described later, and to improve the crystallinity of the capacitor dielectric film, a first alumina film 27 of about 20 nm thickness is formed on the insulating adhesive film 26 by the sputter method.

Next, the steps required until a sectional structure shown in FIG. 1D is obtained will be explained hereunder.

First, a noble metal film, e.g., a platinum film, of about 150 nm thickness is formed on the first alumina film 27 by the sputter method, and this film is used as a first conductive film 31.

Next, a PZT film of about 150 nm thickness is formed on the first conductive film 31 as a ferroelectric film 32 by the sputter method. As the film forming method for the ferroelectric film 32, there are the MOCVD (Metal Organic CVD) method and the sol-gel method in addition to the sputter method. Also, the material of the ferroelectric film 32 is not limited to the PZT. The ferroelectric film 32 may be formed of the Bi layer structure compound such as SrBi₂Ta₂O₉, SrBi₂(Ta,Nb)₂O₉, or the like, PLZT formed by adding lanthanum to PZT, or other metal oxide ferroelectric material.

Subsequently, the RTA (Rapid Thermal Annealing) is applied to the PZT constituting the ferroelectric film 32 in the atmosphere, which contains 1% oxygen and 99% argon, to crystallize the PZT. As the conditions of the RTA, for example, a substrate temperature is set to 720° C., a process time is set to 120 seconds, and a programming rate is set to 100 to 150° C./sec.

Then, an iridium oxide (IrO₂) film of about 250 nm thickness is formed on the ferroelectric film 32 by the sputter method, and this film is used as a second conductive film 33. In this case, the second conductive film 33 may be formed of a noble metal film or a noble metal oxide film. In place of the iridium oxide film, a noble metal film such as an iridium film, a platinum film, or the like may be formed as the second conductive film 33.

Next, as shown in FIG. 1E, the second conductive film 33, the ferroelectric film 32, and the first conductive film 31 are patterned separately in this order by the photolithography. Thus, a lower electrode 31a, a capacitor dielectric film 32a, and an upper electrode 33a are patterned to constitute a ferroelectric capacitor Q. In this case, the first conductive film 31 is patterned such that a contact region CR of the lower electrode 31a extends from the capacitor dielectric film 32a.

Next, the steps required until a sectional structure shown in FIG. 1F is obtained will be explained hereunder.

First, a second alumina film 40 is formed on the overall upper surface of the silicon substrate 10. This second alumina film 40 protects the capacitor Q from the reducing atmosphere, such as hydrogen, and thus prevents the deterioration of the capacitor dielectric film 32a. The second alumina film 40 is formed by the sputter method, for example, to have a thickness of about 20 nm.

Then, in order to recover the capacitor dielectric film 32a from the damage caused by the etching, the sputtering, and the like in the steps performed up to now, the recovery annealing is carried out in the 100% oxygen atmosphere in the furnace under the conditions of the substrate temperature 650° C. and the process time 90 minutes.

Next, a silicon oxide film 41 of about 1500 nm thickness is formed on the second alumina film 40 by the plasma CVD method using the TEOS gas as a reaction gas. Reflecting the shape of the capacitor Q, concavity and convexity are formed on an upper surface of the silicon oxide film 41. In order to eliminate these concavity and convexity, the upper surface of the silicon oxide film 41 is polished and planarized by the CMP method, thereby reducing a thickness of the silicon oxide film 41 on the flat surface of the second alumina film 40 to about 1000 nm.

Thereafter, as the dehydrating process of the silicon oxide film 41, the surface of the silicon oxide film 41 is exposed to the N₂O plasma. Instead of such N₂O plasma, the silicon oxide film 41 may be annealed in the furnace to dehydrate it.

Next, in order to protect the capacitor Q from the hydrogen or the water content generated in later steps, a third alumina film 42 of about 50 nm thickness is formed on the silicon oxide film 41 by the sputter method. Furthermore, a silicon oxide film 43 of about 200 nm thickness is formed on the third alumina film 42 by the plasma CVD method.

With the steps performed up to now, a second interlayer insulating film 44 consisting of the silicon oxide films 41, 43 and the third alumina film 42 is formed on the capacitor Q.

Subsequently, as shown in FIG. 1G, the photoresist is coated on the second interlayer insulating film 44, and then exposed and developed. Thus, a first resist pattern 45 having first and second windows 45a, 45b of hole shape is formed.

Next, the steps required until a sectional structure shown in FIG. 1H is obtained will be explained hereunder.

First, the silicon substrate 10 is put into the parallel plate type plasma etching chamber, and then the substrate temperature is stabilized at about −10 to 10° C. Then, a gas mixture consisting of C₄F₈, Ar, O₂, and CO is introduced into the chamber as an etching gas, and a pressure in the chamber is set to about 4 to 7 Pa. In this condition, the high-frequency power whose frequency is 27.12 MHz and whose power is 2200 W is applied to an upper electrode (not shown) in the chamber to generate the plasma in the chamber. According to this, the second interlayer insulating film 44 and the underlying second alumina film 40 are etched via the first and second windows 45a, 45b in the first resist pattern 45. Thus, a first hole 44a is formed on the upper electrode 33a and a second hole 44b is formed on the contact region CR of the lower electrode 31a.

Here, a flow rate of the etching gas is not particularly limited. In this example, C₄F₈ is set to 10 to 20 sccm, Ar is set to 300 to 500 sccm, O₂ is set to 10 to 20 sccm, and CO is set to 0 to 50 sccm.

Next, as shown in FIG. 1I, interiors of the first and second holes 44a, 44b are cleaned by dipping the silicon substrate 10 in a 60 to 70 wt % nitric acid for about 30 seconds. Then, the first resist pattern 45 is removed by the ashing using the oxygen plasma. A process time of this ashing is about 90 seconds, for example.

Meanwhile, when forming the foregoing first and second holes 44a, 44b by the etching, the above etching is performed like the over-etching to prevent that these holes 44a, 44b are not opened. For this reason, at the time of this etching, upper surfaces of the upper electrode 33a and the lower electrode 31a under respective holes 44a, 44b are slightly etched, so that constitutive materials of respective electrodes 33a, 31a are emitted into the etching atmosphere.

As a result, as shown in FIG. 1I, etching products 38 containing the above material, e.g., the iridium oxide and the platinum, are left around the first and second holes 44a, 44b after the first resist pattern 45 is removed.

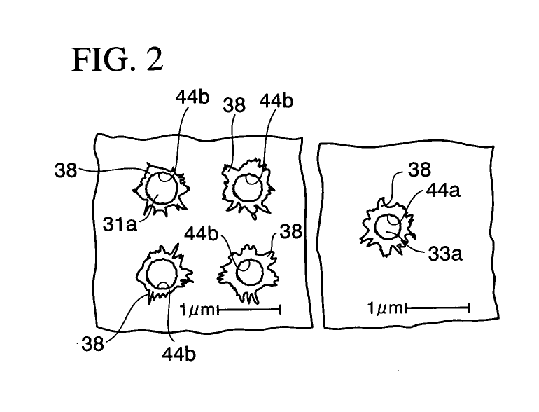

FIG. 2 is a view of the first and second holes 44a, 44b drawn based on their SEM (Scanning Electron Microscope) images after these steps are completed, wherein the left side in FIG. 2 is the second hole 44b and the right side in FIG. 2 is the first hole 44a.

As shown in FIG. 2, the above etching product 38 is generated around both the first hole 44a from which the upper electrode 33a is exposed and the second hole 44b from which the lower electrode 31a is exposed.

Therefore, as shown in FIG. 1J, in order to remove such etching products 38, the silicon substrate 10 is dipped in the 60 to 70 wt % nitric acid for about 30 seconds.

However, since the etching products 38 contain the iridium oxide that is derived from the upper electrode 33a and lacks a reactivity, such etching products 38 cannot be dissolved completely and cannot be removed by the chemical wet process using the above nitric acid. Therefore, the etching products 38 are caused to float in the solution during the wet process and then are adhered onto the second interlayer insulating film 44 again, as shown in FIG. 1J.

Here, the constitutive material of the lower electrode 31a exposed from a second hole 44b, e.g., the noble metal such as the platinum, and the alumina in the third alumina film 42 exposed from the first and second holes 44a, 44b are contained in the etching products 38. Some of alumina is derived from the second alumina film 40 under respective holes 44a, 44b. It may be considered that, since the noble metal and the alumina lack the reactivity, these materials make it difficult to chemically remove the etching products 38.

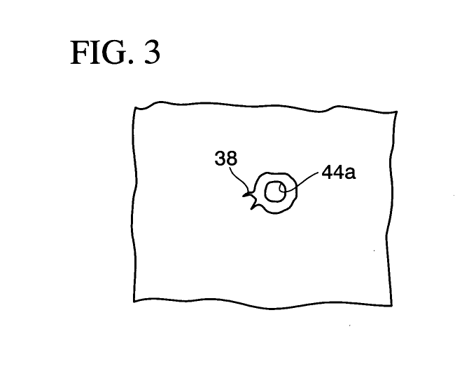

FIG. 3 is a view of the first hole 44a drawn based on its SEM image after these steps are completed. As shown in FIG. 3, a part of the etching products 38 is still left around the first hole 44a after the wet process is applied by the nitric acid.

Then, as shown in FIG. 1K, the photoresist is coated again on the second interlayer insulating film 44, and then exposed and developed. Thus, a second resist pattern 47, in which third to fifth windows 47c to 47e of are shaped like a hole on the first to third contact plugs 22a to 22c respectively, is formed. In this case, the first and second holes 44a, 44b are covered with the second resist pattern 47.

As the result that the etching products 38 is adhered again onto the second interlayer insulating film 44, some of the windows 47c to 47e are formed to overlap with the etching product 38 in some cases. In an example of FIG. 1K, the third window 47c is formed to overlap with the etching product 38.

Next, as shown in FIG. 1L, the second interlayer insulating film 44, the first and second alumina films 27, 40, and the insulating adhesive film 26 are etched via the third to fifth windows 47c to 47e. Thus, third to fifth holes 44c to 44e are formed on the contact plugs 22a to 22c respectively. Such etching is performed in the parallel plate type plasma etching equipment using a gas mixture consisting of C₄F₈, Ar, O₂, and CO as an etching gas. The oxidation preventing film 25 acts as an etching stopper film, and the etching is stopped on the oxidation preventing film 25. Here, a flow rate of the etching gas is not particularly limited. In this example, C₄F₈ is set to 10 to 20 sccm, Ar is set to 300 to 500 sccm, O₂ is set to 10 to 20 sccm, and CO is set to 0 to 50 sccm. Also, the substrate temperature is set to −30 to 0° C., and a pressure in the chamber is set to about 4 to 7 Pa. Also, the high-frequency power whose frequency is 27.12 MHz and whose power is 1500 to 2200 W is applied to the upper electrode (not shown) in the chamber, and accordingly the above etching gas is plasmanized.

Out of the third to fifth holes 44c to 44e formed in this manner, the fourth and fifth holes 44d, 44e are formed normally.

In contrast, a diameter of the third hole 44c becomes small since the etching product 38 acts as a mask, and its diameter is extremely reduced in the lower portion.

Thereafter, the second resist pattern 47 is removed.

Next, the steps required until a sectional structure shown in FIG. 1M is obtained will be explained hereunder.

First, the silicon substrate 10 is put into the parallel plate type plasma etching chamber, and then a gas mixture consisting of CHF₃, Ar, and O₂ is supplied to the etching equipment as an etching gas. According to this, the oxidation preventing film 25 under the third to fifth holes 44c to 44e is exposed to the etching atmosphere and removed, and thus the first to third contact plugs 22a to 22c are exposed from these holes. Also, extraneous substances in the first and second holes 44a, 44b are removed, and thus the upper surfaces of the upper electrode 33a and the lower electrode 31a are cleaned.

Here, the etching conditions are not particularly limited. In this example, flow rates of CHF₃, Ar, and O₂ is set to 30 to 50 sccm, 300 to 500 sccm, and 10 to 20 sccm respectively. Also, the substrate temperature is set to 0 to 20° C., and a pressure in the chamber is set to about 4 to 7 Pa. In addition, the high-frequency power whose frequency is 27.12 MHz is applied to the upper electrode, which is also used as the showerhead in the chamber, at the power of 1000 to 1500 W.

In this manner, the deep third to fifth holes 44c to 44e are formed on the first to third source/drain regions 13a to 13c, in the steps that are different from those applied to form the shallow first and second holes 44a, 44b on the capacitor Q.

It may be considered that all holes 44a to 44e are formed simultaneously. However, according to such process, an etching time must be set in accordance with the deep third to fifth holes 44c to 44e. As a result, the upper electrode 33a located under the first hole 44a, which is shallower than the third to fifth holes 44c to 44e and opened for a short time, is exposed to the etching atmosphere for a long time. Such situation is not preferable since the capacitor dielectric film 32a under the upper electrode 33a is deteriorated by the etching atmosphere.

On the contrary, in the present embodiment, as described above, the first and second holes 44a, 44b and the deep third to fifth holes 44c to 44e are formed separately. When forming the third to fifth holes 44c to 44e, the first and second holes 44a, 44b are covered with the second resist pattern 47. Thus, it can be suppressed that the capacitor dielectric film 32a is deteriorated.

In addition, since the first to third contact plugs 22a to 22c are covered with the oxidation preventing film 25 until the present step is completed, it can be prevented that the tungsten constituting the contact plugs 22a to 22c is oxidized to cause the contact failure.

Next, the steps required until a sectional structure shown in FIG. 1N is obtained will be explained hereunder.

First, in order to clean the inner surfaces of the first to fifth holes 44a to 44e, the inner surfaces of respective holes 44a to 44e are exposed to the argon atmosphere plasmanized by the high-frequency power and thus sputter-etched. An etching depth is set to about 10 nm in terms of film thickness of the silicon oxide film, for example. Then, a titanium nitride film of about 75 nm thickness is formed as a glue film on inner surfaces of the first to fifth holes 44a to 44e and an upper surface of the second interlayer insulating film 44 by the sputter method.

Then, a tungsten film is formed on the glue film by the CVD method such that the first to fifth holes 44a to 44e are buried completely by the tungsten film.

Thereafter, the extra glue film and the extra tungsten film on the upper surface of the second interlayer insulating film 44 are polished and removed by the CMP method, and these films are left in the holes 44a to 44e. These films left in the first and second holes 44a, 44b are used as first and second conductive plugs 50a, 50b that are electrically connected to the upper electrode 33a and the contact region CR of the lower electrode 31a respectively. Also, these films left in the third to fifth holes 44c to 44e are used as third to fifth conductive plugs 50c to 50e that are electrically connected to the first to third contact plugs 22a to 22c respectively.

With the above, a basic structure of the FeRAM is completed.

According to this FeRAM manufacturing method, as shown in FIG. 1N, the diameter of the third hole 44c becomes small due to the presence of the etching product 38. Therefore, a contact area between the third conductive plug 50c formed in this third hole 44c and the underlying first contact plug 22a becomes narrow, which raises concern that contact failure is caused. If this is the case, the finally completed FeRAM becomes defective and thus a yield of the FeRAM is lowered.

In view of such problem, the inventors of this application came to realize the embodiment of the present invention explained in the following.

(2) Embodiment of the Present Invention

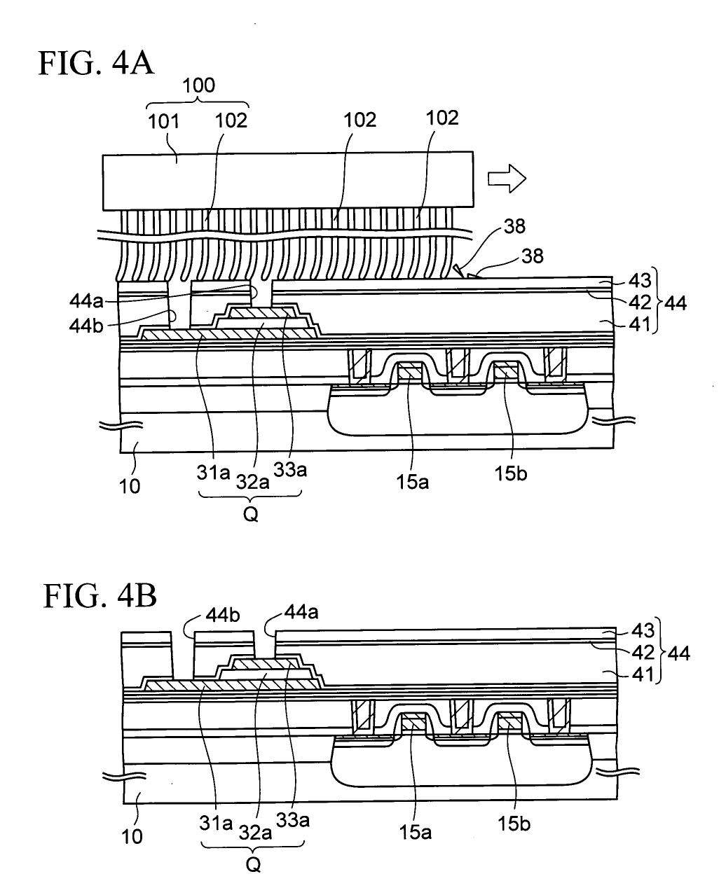

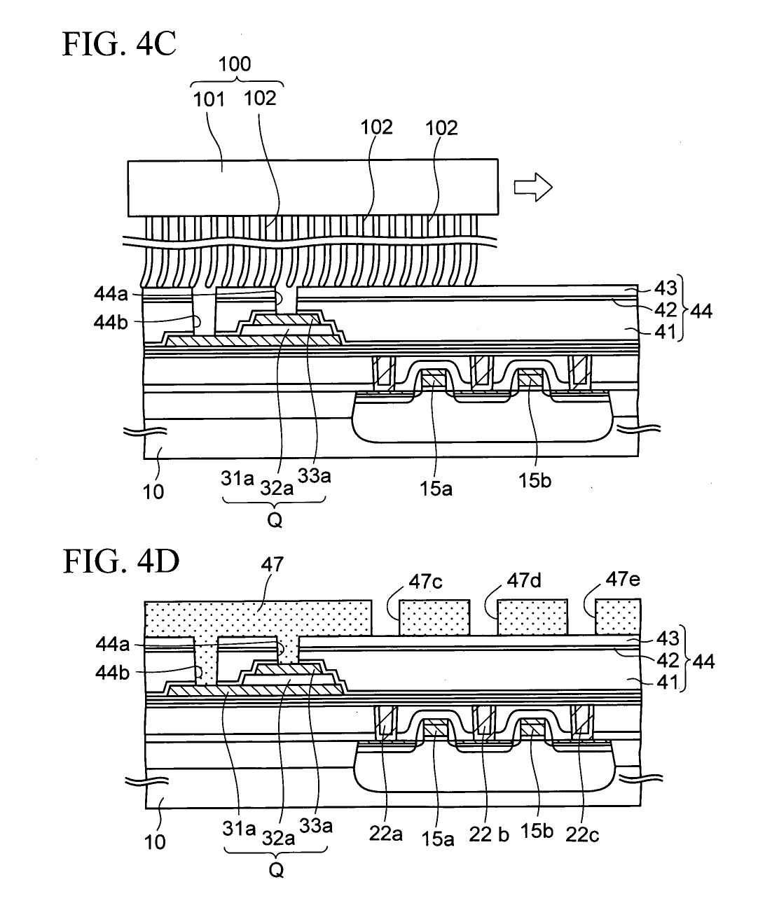

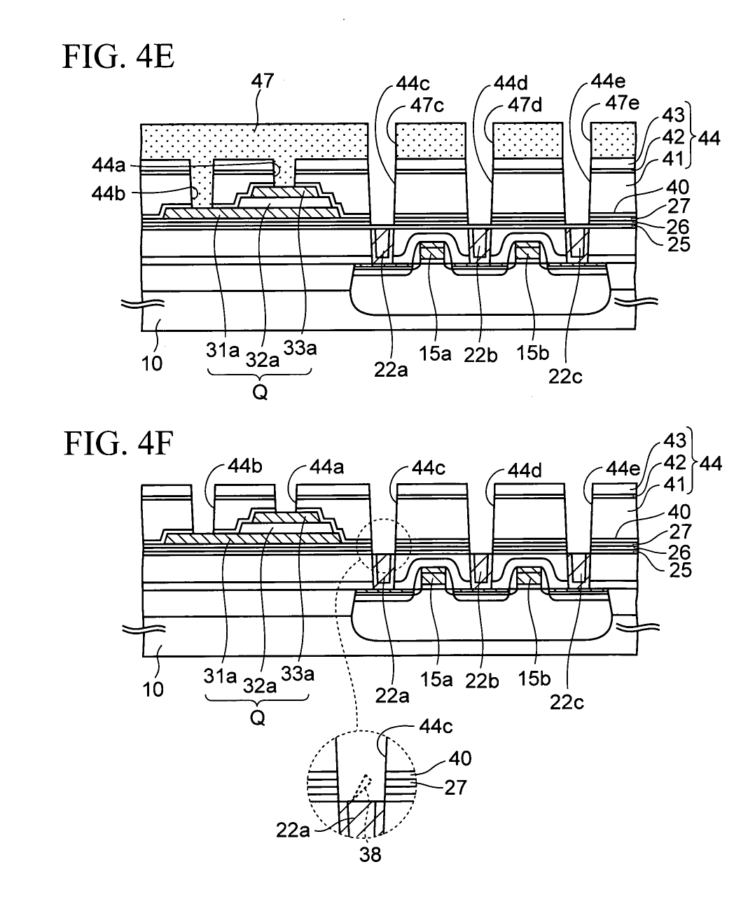

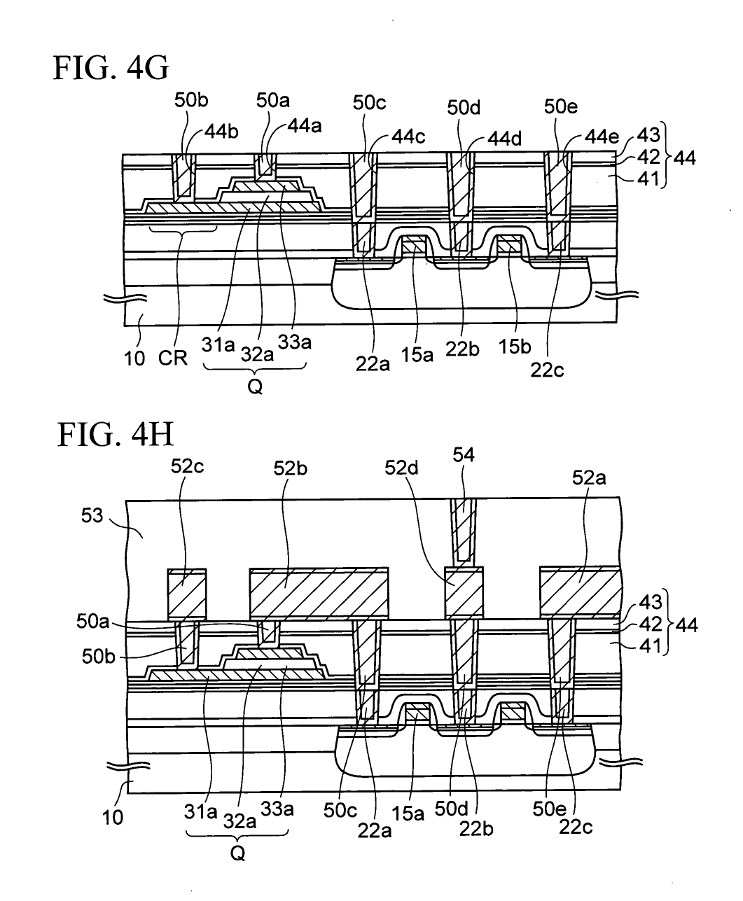

FIGS. 4A to 4H sectional views of a semiconductor device according to an embodiment of the present invention in the middle of manufacture. Here, in FIGS. 4A to 4H, the same reference numerals are affixed to the elements explained in FIGS. 1A to 1N, and their explanation will be omitted hereunder.

First, as explained in the Preliminary Explanation, steps shown in FIGS. 1A to 1H are performed.

Next, as shown in FIG. 4A, a brush scrubber 100, constructed by providing a plurality of brushes 102 to a main body 100, is moved and pressed to the second interlayer insulating film 44, thereby physically removing the etching products 38. Such process is called the brush scrubbing process. Although the conditions of this brush scrubbing process are not limited, a brush load is set to 10 gf/cm² in the present embodiment.

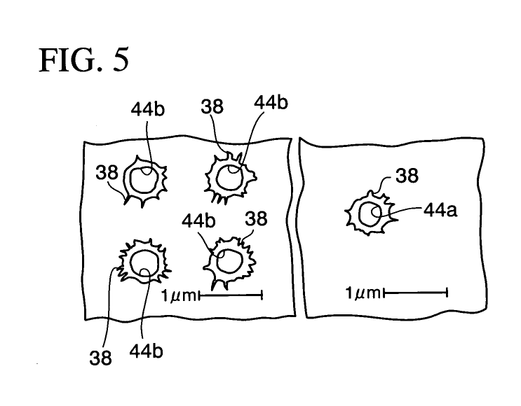

FIG. 5 is a view of the first and second holes 44a, 44b drawn based on their SEM images after this brush scrubbing process is completed, wherein the second holes 44b are shown in the left side of FIG. 5, and the first hole 44a is shown in the right side of FIG. 5.

As apparent from comparing FIG. 2 and FIG. 5, the number of the etching products 38 is reduced by the brush scrubbing process and also a size of the etching product 38 is reduced.

Next, the steps required until a sectional structure shown in FIG. 4B is obtained will be explained hereunder.

First, as the first step of the wet process applied to the second interlayer insulating film 44, the silicon substrate 10 is dipped in the 60 to 70 wt % nitric acid for about 30 seconds. Thus, the etching products 38 that could not be completely removed by the above brush scrubbing process are chemically dissolved and removed.

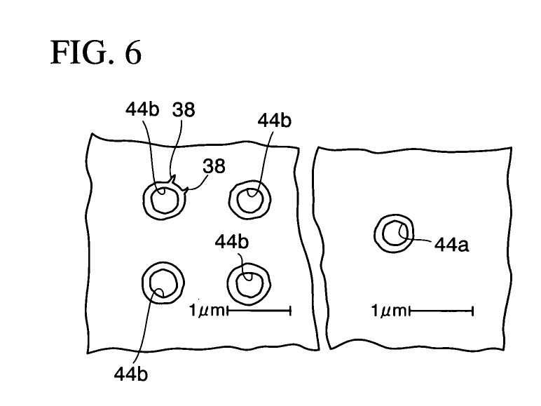

FIG. 6 is a view of the first and second holes 44a, 44b drawn based on their SEM images after the first step of the wet process is completed.

Comparing FIG. 6 and FIG. 5, it can been seen that most of the etching products 38 disappears due to the first step using the nitric acid.

Meanwhile, as described above, etching products 38 contains alumina that is generated when the second and third alumina films 40, 42 exposed from the inner surfaces of the first and second holes 44a, 44b are etched.

In order to remove such alumina content, as the second step of the wet process, the silicon substrate 10 is dipped in the hot water whose temperature is equal to or more than 40° C., and equal to or less than 70° C., more preferably about 50° C., for about 120 seconds after the first step is completed. Since the alumina can be dissolved in the hot water, the alumina content in the etching products 38 can be substantially perfectly removed by this second step.

Here, the reason why a lower limit of the process temperature is set to 40° C. is that, if the temperature is lower than this temperature, the alumina is hard to dissolve and thus it is difficult to remove the alumina content in the etching products 38. Also, the reason why an upper limit of the process temperature is set to 70° C. is that, if the process is conducted at a temperature higher than this temperature, an effect of dissolving the alumina is excessively enhanced and thus the second and third alumina films 40, 42 are dissolved.

Also, it may be considered that a dilute hydrofluoric acid may be employed instead of the hot water. However, if the dilute hydrofluoric acid is employed, the silicon oxide films 41, 43 constituting the second interlayer insulating film 44 are dissolved and the diameter of the first and second holes 44a, 44b is enlarged. Therefore, when such enlargement in the diameter of the first and second holes 44a, 44b is not desired, it is preferable to use the hot water rather than dilute hydrofluoric acid.

Here, in some cases, the etching products 38 still remain on the second interlayer insulating film 44 even after the brush scrubbing process in FIG. 4A and the two-step wet process in FIG. 4B are carried out Therefore, as shown in FIG. 4C, in the next step, the brush scrubbing process is applied to the second interlayer insulating film 44 again to remove perfectly the etching products 38. The conditions of this brush scrubbing process are not particularly limited. In the present embodiment, the brush load is set to 10 gf/cm².

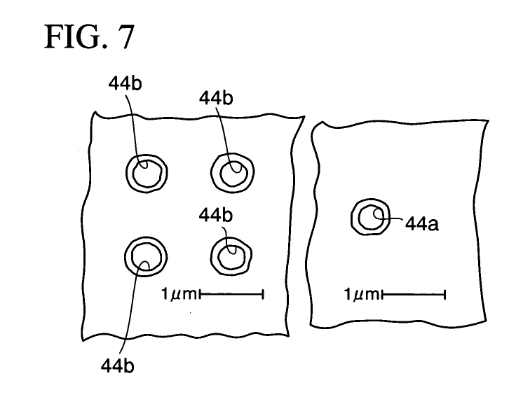

FIG. 7 is a view of the first and second holes 44a, 44b drawn based on their SEM images after the brush scrubbing process in FIG. 4C is completed.

As is apparent from FIG. 7, the etching products 38 generated around the holes 44a, 44b can be removed almost completely by performing the brush scrubbing process.

Then, as shown in FIG. 4D, the photoresist is coated again on the second interlayer insulating film 44 and then exposed and developed, and thus the second resist pattern 47 is formed. The second resist pattern 47 covers the first and second holes 44a, 44b, and the third to fifth windows 47c to 47e of hole shape are provided to the second resist pattern 47 on the first to third contact plugs 22a to 22c.

Since the etching products 38 are removed from the upper surface of the second interlayer insulating film 44 by the brush scrubbing process in FIG. 4A, none of the third to fifth windows 47c to 47e in the second resist pattern 47 overlaps with the etching products 38.

Next, as shown in FIG. 4E, the second interlayer insulating film 44, the first and second alumina films 27, 40, and the insulating adhesive film 26 are etched via the third to fifth windows 47c to 47e. Thus, the third to fifth holes 44c to 44e, which are deeper than the first and second holes 44a, 44b, are formed on the contact plugs 22a to 22c respectively. Here, since the etching conditions are the same as those explained in FIG. 1L, their explanation is omitted here.

Since no etching product 38 is present under the second resist pattern 47 serving as a mask, no defective pattern of the third to fifth holes 44c to 44e is generated by this etching. Therefore, the diameters of these holes have a designed value respectively.

Thereafter, the second resist pattern 47 is removed.

Next, as shown in FIG. 4F, the inner surfaces of the first to fifth holes 44a to 44e are exposed to the etching atmosphere. Thus, the oxidation preventing film 25 exposed from the third to fifth holes 44c to 44e is etched to expose the upper surfaces of the contact plugs 22a to 22c, and also the surfaces of the upper electrode 33a and the lower electrode 31a exposed from the first and second holes 44a, 44b respectively are cleaned. As the etching conditions at this time, the same conditions as those explained in FIG. 1L may be employed.

Meanwhile, as already described, the etching products 38 are substantially perfectly removed by the brush scrubbing process in FIG. 4A and the subsequent wet process in FIG. 4B. However, as shown in a dotted-circle in FIG. 4F, the etching products 38 are not removed and left in the third to fifth holes 44c to 44e in some cases.

In such case, the etching product 38 in the third to fifth holes 44c to 44e is etched and removed by exposing the inner surfaces of these holes 44c to 44e to the etching atmosphere as described above. As a result, contact failure due to the etching product 38 remaining in the third to fifth holes 44c to 44e can be prevented.

Then, as shown in FIG. 4G, the first to fifth conductive plugs 50a to 50e as illustrated are formed in the first to fifth holes 44a to 44e respectively. Since the forming process of these conductive plugs 50a to 50e is similar to that explained in FIG. 1N, its explanation is omitted here.

Next, the steps required until a sectional structure shown in FIG. 4H is obtained will be explained hereunder.

First, a titanium film of about 60 nm thickness and a titanium nitride film of about 30 nm thickness are formed in this order on the second interlayer insulating film 44 and the first to fifth conductive plugs 50a to 50e respectively by the sputter method. These films constitute a barrier metal layer. Then, a copper-containing aluminum film, a titanium film, and a titanium nitride film are formed on the barrier metal layer in this order as a metal laminated film by the sputter method to have a thickness of about 360 nm, 5 nm, and 70 nm respectively.

Then, a silicon oxide nitride film (not shown) is formed as the reflection preventing film on the metal laminated film. After that, the metal laminated film and the barrier metal layer are patterned by the photolithography. Thus, first-layer metal wirings 52a to 52c and a conductive pad 52d are formed.

Next, a silicon oxide film is formed as a third interlayer insulating film 53 by the plasma CVD method, and then this third interlayer insulating film 53 is planarized by the CMP method. Thereafter, a hole is formed on the conductive pad 52d by patterning the third interlayer insulating film 53 by means of the photolithography. Then, a sixth conductive plug 54 made mainly of the tungsten film is formed in the hole.

After these steps, the process goes to the steps that form second to fifth-layer metal wirings and interlayer insulating films between these metal wirings, but their details is omitted here.

With the above, a basic structure of the planar FeRAM according to the present embodiment is completed.

According to the above present embodiment, as shown in FIG. 4A, the brush scrubbing process is applied to the second interlayer insulating film 44 after the first and second holes 44a, 44b are formed by the patterning. In this brush scrubbing process, the etching products 38 generated during the patterning are physically scraped off by the brushes 102. Therefore, the etching products 38 can be removed without fail rather than the case where the etching products 38 are chemically dissolved by the wet process. For this reason, it can be prevented that, when the deep third to fifth holes 44c to 44e are formed in the second interlayer insulating film 44 in the step in FIG. 4E, the holes 44c to 44e are not opened due to the presence of the etching product 38. Hence, the third to fifth conductive plugs 50c to 50e (see FIG. 4H) formed in these holes 44c to 44e can be brought surely into electrical contact with the underlying first to third contact plugs 22a to 22c. As a result, the contact failure of the third to fifth conductive plugs 50c to 50e can be suppressed, and in turn a yield of the FeRAM can be improved.

In addition, after the brush scrubbing process is executed, as explained in FIG. 4B, the wet process having the surface process using the nitric acid as the first step is applied to the second interlayer insulating film 44. Therefore, the etching products 38 that could not removed by the brush scrubbing process are dissolved, so that the etching products 38 can be removed more surely.

In particular, like the present embodiment, the alumina is contained in the etching products 38 when the first and second holes 44a, 44b are formed to pass through the second and third alumina films 40, 42. In this case, because the second step of exposing the second interlayer insulating film 44 to the hot water is executed after the first step, the alumina content in the etching products 38 can be dissolved into the hot water and removed.

Further, in the step of exposing the inner surfaces of the first to fifth holes 44a to 44e to the etching atmosphere as shown in FIG. 4F, the surfaces of the lower electrode 31a and the upper electrode 33a are cleaned and also the etching products 38 left in the third to fifth holes 44c to 44e are etched and removed. Therefore, it can be prevented that the contact failure of the third to fifth conductive plugs 50c to 50e (see FIG. 4H) is generated by the etching products 38 in the third to fifth holes 44c to 44e.

In the above, the planar FeRAM in which the second conductive plug 50b is formed on the contact region CR of the lower electrode 31a is explained. However, the present invention is not limited to this type. For example, the present invention can be applied to the stacked FeRAM in which the conductive plug connected electrically to the lower electrode 31a is formed directly under the lower electrode.

According to the present invention, since the etching products generated in forming the holes in the interlayer insulating film are physically scraped off by the brush scrubbing process, a removing efficiency is very high rather than the case where the etching products are removed only by the chemical process. Therefore, even when another holes are formed in the interlayer insulating film after the brush scrubbing process, it can be prevented that the holes are not opened due to the etching products. As a result, the contact failure between the conductive plugs formed in the holes and the underlying layer can be prevented, and in turn a yield of the semiconductor device can be improved.

What is claimed is:

1. A semiconductor device manufacturing method, comprising;
a step of forming a MOS transistor on a semiconductor substrate;
a step of forming a first interlayer insulating film on the MOS transistor;
a step of forming a contact hole in the first interlayer insulating film on a source/drain region of the MOS transistor;
a step of forming a contact plug connected electrically to the source/drain region in the contact hole;
a step of forming an oxidation preventing film on the first interlayer insulating film and the contact plug;
a step of forming a capacitor having a lower electrode, a capacitor dielectric film, and an upper electrode on the oxidation preventing film;
a step of forming a second interlayer insulating film that covers the capacitor;
a step of forming a first hole having a depth, which reaches the upper electrode, in the second interlayer insulating film by patterning the second interlayer insulating film;
a step of applying a brush scrubbing process to a surface of the second interlayer insulating film after the second interlayer insulating film is patterned;
a step of applying a wet process to the surface of the second interlayer insulating film after the brush scrubbing process;
a step of forming a second hole in the second interlayer insulating film on the contact plug by patterning the second interlayer insulating film, while using the oxidation preventing film as an etching stopper, after the wet process;
a step of etching the oxidation preventing film exposed from the second hole to expose an upper surface of the contact plug and also cleaning an upper surface of the upper electrode exposed from the first hole, by exposing inner surfaces of the first and second holes to an etching atmosphere;
a step of forming a first conductive plug connected electrically to the upper electrode in the first hole; and
a step of forming a second conductive plug connected electrically to the contact plug in the second hole.

2. A semiconductor device manufacturing method, according to claim 1, wherein a laminated film containing an alumina film is formed as the second interlayer insulating film.

3. A semiconductor device manufacturing method, according to claim 2, wherein the surface of the second interlayer insulating film is exposed to a hot water in the wet process.

4. A semiconductor device manufacturing method, according to claim 3, wherein a temperature of the hot water is equal to or more than 40° C., and equal to or less than 70° C.

5. A semiconductor device manufacturing method, according to claim 1, wherein the surface of the second interlayer insulating film is exposed to a nitric acid in the wet process.

6. A semiconductor device manufacturing method, according to claim 1, wherein the brush scrubbing process is applied again to the surface of the second interlayer insulating film after the wet process.

7. A semiconductor device manufacturing method, according to claim 1, wherein a silicon oxide nitride film is formed as the oxidation preventing film.

8. A semiconductor device manufacturing method, according to claim 1, wherein a noble metal film or a noble oxide metal film is employed as the upper electrode.

9. A semiconductor device manufacturing method, according to claim 1, wherein, in the step of forming the capacitor, a contact region of the lower electrode is formed to extend from the capacitor dielectric film, and
in the step of forming the first hole in the second interlayer insulating film, a third hole having a depth that reaches the contact region of the lower electrode is formed in the second interlayer insulating film, and
further comprising:
a step of forming a third conductive plug connected electrically to the lower electrode in the third hole.

10. A semiconductor device manufacturing method, according to claim 9, wherein a noble metal film is employed as the lower electrode.

11. A semiconductor device manufacturing method, according to claim 1, wherein, in the step of forming the second hole, the first hole is covered with a resist pattern.
